(19) United States
(12) Patent Application Publication
(10) Pub. No.: US 2005/0077600 A1
(43) Pub. Date: Apr. 14, 2005

(54) Semiconductor device

(75) Inventor: Hisakazu Kotani, Hyogo (JP)

Correspondence Address: MCDERMOTT WILL & EMERY LLP, 600 13TH STREET, N.W., WASHINGTON, DC, 20005-3096, US

(73) Assignee: MATSUSHITA ELECTRIC INDUSTRIAL CO., LTD.

(21) Appl. No.: 10/952,796

(22) Filed: Sep. 30, 2004

(30) Foreign Application Priority Data
Sep. 30, 2003 (JP) P. 2003-339369

(51) Int. Cl. H01L 23/58; H01L 29/10; H01L 23/495

(52) U.S. Cl. 257/672

(57) ABSTRACT

The SIP structure package includes a first chip though which signal transmission/reception is performed between the inside and the outside of the package, and a second chip connected to the first chip within the package. The first chip includes interface circuits 6A and 6B for supplying a signal to all the signal terminals of the second chip. The operation of the interface circuits is controlled to be stoppable by a control signal.

### BACKGROUND OF THE INVENTION

1. Field of the Invention

This invention relates to a semiconductor device in which a plurality of chips mounted in the same package are connected to one another

2. Description of the Related Art

In recent years, with development of large-scaling of an LSI and complication of a manufacturing process, the number of system LSIs each having a system-in-package (hereinafter referred to as SIP) structure in which a plurality of chips are mounted on the same package has been increased. Concretely, for example, as disclosed in JP-A-2001-267488 (page 20, FIG. 1), another chip is stacked on one chip and these chips are connected to each other by wire bonding. In this way the two chips constitute a single LSI.

Conventionally in the LSI having the SIP structure, as disclosed in JP-A-2002-131400 (page 13, FIG. 1), connection(s) among the chips on the same package is confirmed by the technique in which a testing resistor is provided at the connecting portion between the chips to measure the leak current, thereby testing the connection between the chips.

However, in the LSIs having the SIP structure described in the Background Art, important things are not only the technique of confirming the connection between the chips after mounted, but also the techniques of confirming the delay characteristic such as the access time between the chips, current consumed at the connecting portion between the chips and static current for each chip. As the case may be, after shipped in a market, a device characteristic or mounting characteristic may be changed owing to the problem of reliability. For example, the resistance at the connecting portion between the chips may be increased or the access characteristic of the incorporated memory chip may be deteriorated.

In such a case, the LSI having the SIP structure must be subjected to failure analysis to specify the cause of characteristic changes. The characteristics of the respective chips within the SIP structure must be evaluated. In the conventional configuration, it was difficult to evaluate the characteristic of the individual chip and that between the chips.

For example, as shown in FIG. 13, in the LSI in which a first chip 1 and a second chip are connected by wires within the same package, a VDD terminal for a power source is generally connected commonly to the first chip and second chip because of the limitation of the number of pins. In this configuration, where the operating current for the second chip 2 is measured, the second chip 2 is controlled through interface circuits 6A and 6B provided on the first chip 1 from the outside of the LSI to evaluate the operating current. In this case, the current (I1+I2+I5) consumed in the interface circuits 6A and 6B is superposed on the operating current (I3+I4) consumed in the second chip 2 (as a result, ICC=I1+I2+I3+I4+I5) so that the operating current (I3+I4) consumed in only the second chip can be known.

In FIG. 13, on the first chip 1, outer pads inclusive of a control terminal 3A, an address terminal 3B, an output terminal 3C and a VDD terminal (power source terminal) 3D are provided. On the periphery of the second chip 2 on the first chip 1, inner pads 4A, 4B and 4C are provided. On the second chip 2, inner pads 5A, 5B, 5C and 5D which are connected to the inner pads 4A, 4B, 4C and 3D through wires, respectively are provided.

Where the chips are connected within the package in the SIP structure, the load condition of signal transmission/reception between the chips is not dear. In the case of a memory, the characteristic values such as an access time and a consumed current greatly correspond to an output load capacity. On the specification of the memory unit, the test condition is described as the output load capacity of 30 pF to 50 pF. On the other hand, in the case of the SIP structure, it is difficult to accurately evaluate the characteristic values such as the access time and consumed current on the condition of several pF.

### SUMMARY OF THE INVENTION

This invention has been accomplished in view of the above inconvenience. This invention intends to provide a means for measuring the operating current of an individual chip within an SIP structure package. This invention also intends to provide a means for measuring the static current of an individual chip. This invention further intends to provide a means for measuring the access time in a real load condition at the connecting portion between the chips within the package.

In order to attain the above object, this invention provides a first semiconductor device in which a plurality of chips mounted in the same package are connected to one another by wires or bumps, wherein
the plurality of chips include a first chip though which signal transmission/reception is performed between the inside and the outside of the package, and a second chip connected to the first chip within the package, the first chip includes an interface circuit for supplying a signal to all the signal terminals of the second chip, and the operation of the interface circuit is controlled to be stoppable by a control signal.

In accordance with the first semiconductor device, since the operation of the interface circuit can be controlled by the control signal, if the operation of the interface circuit is stopped partially or completely, the first chip and the second chip are discriminated from each other so that the operating current of each individual chip and that at a connecting portion between the chips can be measured.

This invention provides a second semiconductor device according to the first semiconductor device, further comprising a switch element for connecting a part of an external signal terminal through which the signal is externally supplied to the first chip, to an inner signal terminal of the first chip through which the signal is supplied to the second chip, the switch element is turned on by the control signal.

In accordance with the second semiconductor device, since the switch element which is turned on by the control signal is provided in order to measure the operating current, if the operating current is measured once by turn-on of the switch element, the operating current for each individual chip and that at the connecting portion between the chips can be measured.

This invention provides a third semiconductor device in which a plurality of chips mounted in the same package are connected to one another by wires or bumps, wherein
the plurality of chips indude a first chip though which signal transmission/reception is performed between the inside and the outside of the package, and a second chip connected to the first chip within the package,
further comprising a first power source line for supplying a power source to the first chip through a first switch element, and a second power source line for supplying the power source to the second chip through a second switch element.

In accordance with the third embodiment, since the power source line is provided for each individual chip, the static current for each individual chip can be measured.

This invention provides a fourth semiconductor device in which a plurality of chips mounted in the same package are connected to one another by wires or bumps, wherein
the plurality of chips indude a first chip though which signal transmission/reception is performed between the inside and the outside of the package, and a second chip connected to the first chip within the package,
further comprising a first flip-flop for fetching the signal to be inputted from the first chip to the second chip, a second flip-flop for fetching the signal to be outputted from the second chip and a terminal through which outputs from the first and the second flip-flop are outputted to the outside of the package.

In accordance with the fourth semiconductor device, since there are provided the first flip-flop for fetching the signal to be inputted from the first chip to the second chip and the second flip-flop for fetching the signal to be outputted from the second chip so that the outputs from the first and second flip-flops are outputted to the outside of the package. In this configuration, the delayed status of the signal between the chips can be monitored, thereby measuring the access time in a real load state at the connecting portion between the chips within the package.

This invention provides a fifth semiconductor device in which a plurality of chips mounted in the same package are connected to one another by wires or bumps, wherein
the plurality of chips indude a first chip though which signal transmission/reception is performed between the inside and the outside of the package, and a second chip connected to the first chip within the package,
further comprising a first flip-flop for fetching the signal to be inputted from the first chip to the second chip, a second flip-flop for fetching the signal to be outputted from the second chip at a different timing from that for the first flip-flop, a logic element for making a logic operation of outputs from the first and second flip-flops, and a terminal which through the output from the logic element is outputted to the outside of the package.

In accordance with the fifth semiconductor device, there are provided a first flip-flop for fetching the signal to be inputted from the first chip to the second chip and a second flip-flop for fetching the signal to be outputted from the second chip at a different timing from that for the first flip-flop so that the timing of fetching the input signal in the second chip and the timing of fetching the signal to be outputted from the second chip are individually controlled. In this configuration, it is not necessary to measure the access time twice in monitoring the signal between the chips. The access time from the first chip to the second chip can be obtained by the measurement once made. Further, since the outputs from the flip-flops are collected by the logic element, the access time within the package can be monitored at a single terminal without increasing the number of external pins.

This invention provides a sixth semiconductor device according to the fifth semiconductor device, further comprising a delay circuit for delaying a clock signal supplied to the first flip-flop and supplying the delayed clock signal to the second flip-flop.

In accordance with the sixth semiconductor device, since the clock signal supplied to the first flip-flop is delayed and the delayed clock signal is supplied to the second flip-flop, the clock signal can be commonly used, thereby reducing the number of external pins for supplying the clock signal.

This invention provides a seventh semiconductor device in which a plurality of chips mounted in the same package are connected to one another by wires or bumps, wherein
the plurality of chips indude a first chip though which signal transmission/reception is performed between the inside and the outside of the package, and a second chip connected to the first chip within the package,
further comprising a signal transition detecting circuit for detecting a transition in the signal inputted from the first chip to the second chip, a flip-flop for fetching the signal to be outputted from the chip at an output timing of the signal transition detecting circuit, and a terminal through which the output from the flip-flop is outputted to the outside of the package.

In accordance with the seventh semiconductor device, there are provided a signal transition detecting circuit for detecting a transition in the signal inputted from the first chip to the second chip and a flip-flop for fetching the signal to be outputted from the second chip at an output timing of the signal transition detecting circuit so that the output from the flip-flop is outputted to the outside of the package. In this configuration, it is not necessary to measure the access time twice in monitoring the signal between the chips. The access time from the first chip to the second chip can be obtained by the measurement once made. Further, since the signal outputted from the second chip is fetched at the timing when the transition level of the signal inputted from the first chip into the second chip varies, without scanning the signal inputted externally and increasing the number of external pins, the access time within the package can be monitored at a single terminal.

In accordance with this invention, since the operation of the interface circuit can be controlled by a control signal, if the operation of the interface circuit is stopped partially or completely, the first chip and the second chip can be discriminated so that the operating current of the individual chip and that of the connecting portion between the chips can be measured. Further, if the power source line for each chip is individually provided, the static current for each chip can be measured. Furthermore, there are provided the first flip-flop for fetching the signal to be inputted from the first chip to the second chip and the second flip-flop for fetching the signal to be outputted from the second chip so that the outputs from the first and second flip-flops are outputted to the outside of the package. In this configuration, the delayed status of the signal between the chips can be monitored, thereby measuring the access time in a real load state at the connecting portion between the chips within the package. Accordingly, the semiconductor device according to this invention is useful to specify the cause when failure in the device occurred.

### BRIEF DESCRIPTION OF THE DRAWINGS

FIG. 1 is a block diagram showing a semiconductor device according to the first embodiment of this invention.

FIG. 2 is a block diagram showing a semiconductor device according to the second embodiment of this invention.

FIG. 3 is a block diagram showing a semiconductor device according to the third embodiment of this invention.

FIG. 4 is a block diagram showing a semiconductor device according to the fourth embodiment of this invention.

FIG. 5 is a timing chart of signals at the respective positions of the semiconductor device shown in FIG. 4.

FIG. 6 is a timing chart of signals at the respective positions of the semiconductor device shown in FIG. 4. device according to the third embodiment of this invention.

FIG. 7 is a block diagram showing a semiconductor device according to the fifth embodiment of this invention.

FIG. 8 is a timing chart of signals at the respective positions of the semiconductor device shown in FIG. 7.

FIG. 9 is a block diagram showing a semiconductor device according to the sixth embodiment of this invention.

FIG. 10 is a timing chart of signals at the respective positions of the semiconductor device shown in FIG. 9.

FIG. 11 is a block diagram showing a semiconductor device according to the seventh embodiment of this invention.

FIG. 12 is a timing chart of signals at the respective positions of the semiconductor device shown in FIG. 11.

FIG. 13 is a block diagram showing a conventional semiconductor device.

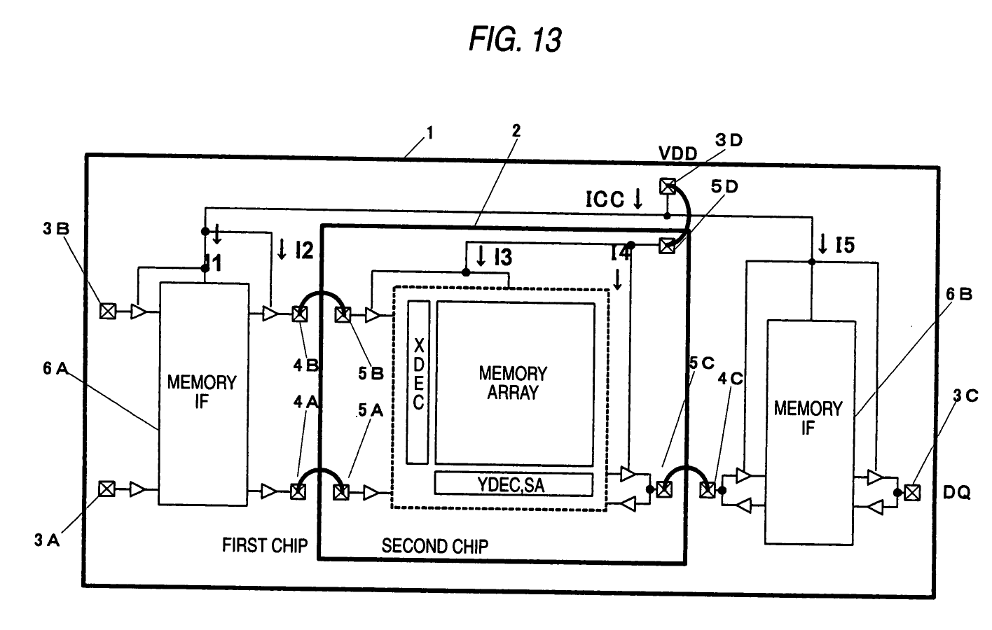

### DESCRIPTION OF THE PREFERRED EMBODIMENTS

Now referring to the drawings, an explanation will be given of various embodiments.

### Embodiment 1

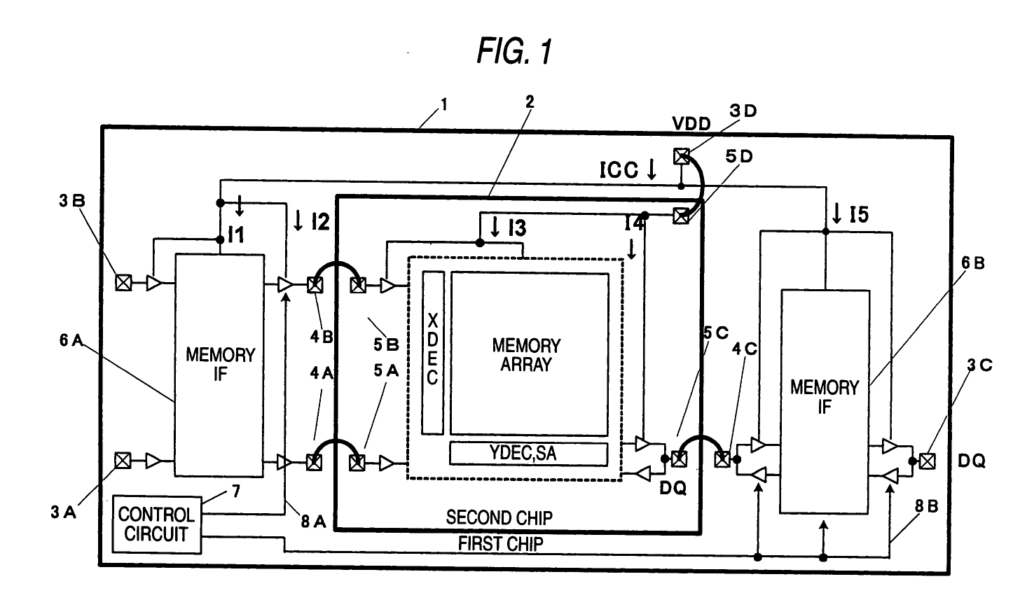

FIG. 1 is a block diagram of a semiconductor device according to the first embodiment of this invention. In this semiconductor device, the first chip 1 and second chip 2 are connected by wires and are mounted in the same package. The first chip 1 is provided with outer pads inclusive of a control terminal 3A through which signal transmission/reception is performed between the inside and outside of the package, an address terminal 3B, output terminal 3C and power source terminal 3D.

On the other hand, in the second chip 2, signal exchange is not carried out between the inside and outside of the package. In order to carry out the signal exchange between the first chip 1 and the second chip 2 through wires, there are provided inner pads 4A, 4B and 4C of the first chip 1 and inner pads 5A, 5B and 5C of the second chip 2. The second chip 3 is also provided with an inner pad 5D which is a power source terminal connected to the power source terminal 3D through a wire. Incidentally, the inner pads 4A, 4B and 4C and the corresponding inner pads 5A, 5B and 5C are connected through wires, respectively.

In the example of FIG. 1, the inner pads 4A, 4B and 4C of the first chip 1 and the corresponding inner pads 5A, 5B and 5C of the second chip 2 are connected through wires. Instead of the wires, bumps may be employed to connect the first chip 1 and the second chip 2.

The second chip 2 is assumed to be a memory element. The first chip 1 includes interfaces 6A and 6B through which signal transmission/reception is performed between the inside and outside of the package. As described above, the second chip 2 does not directly execute the signal exchange between the inside and outside of the package. The second chip 2 receives a control signal and an address signal from the first chip 1 through the inner pads 4A, 5A and 4B, 5B and transmits a DQ signal which is a data output, through the inner pads 5C, 4C, to logic circuits such a control circuit and CPU within the first chip 1, which are not shown in FIG. 1.

Generally, in the package including the chips configured as shown in FIG. 1, in order that the second chip 2 which cannot be monitored externally can be tested in the chip test after assembled in the package, a signal is transmitted to or received from the respective terminals of the second chip 2. On the first chip 1, a control circuit 7 is provided for stopping partially or completely the operation of the interface circuits 6A and 6B when the operating current is measured.

In the package having the configuration described above, when the operating current supplied from the outside of the package is measured, as described above, conventionally, it was difficult to discriminate the operating currents of the first chip 1 and the second chip 2 from each other. In order to solve such a problem, this embodiment is characterized by stopping partially or completely the operation of the interface circuits 6A and 6B in an operation mode of measuring the operating current. The stopping control of the interface circuits 6A and 6B, as shown in FIG. 1, is executed by transmitting, from the control circuit, an input side stopping signal 8A and an output side stopping signal 8B for the interface circuits 6A and 6B to the input side and output side of the second chip 2, respectively Incidentally, although not shown, the stopping signal may be directly transmitted from the control terminal 3A of the first chip 1.

The measurement of the operating current will be further explained. In this embodiment as shown in FIG. 1, the second chip 2 is assumed to be a memory chip. The control signal supplied to the control terminal 3A, although not shown, is assumed to be a chip enable signal CE or output buffer enable signal OE. The operating current is measured in the following modes.

(1) Control terminal 3A (CE, OE): disable; address terminal 3B: optional operation; output signal of the inner pad 4C: disable.

The operating current ICC measured in this mode: I1

(2) Control terminal 3A(CE, OE): disable; address terminal 3B: optional operation; output signal of the inner pad 4C: enable.

The operating current ICC measured in this mode: I1+I2

(3) Control terminal 3A: CE enable, OE disable; address terminal 3B: optional operation.

The operating current ICC measured in this mode: I1+I2+I3

(4) Control terminal 3A: CE, OE enable; address terminal 3B: optional operation; output side interface circuit 6B: off. The operating current ICC measured in this mode: I1+I2+I3+I4

By measuring the operating current of the second chip 2 in the modes of the above (2) and (4), the operating current of only the second chip 2 indicated by ICC=I3+I4 can be measured. Further, by evaluating the operating currents in the modes of (1) and (2), the current consumed on the input signal sides of the inner pads 4A, 4B and 5A, 5B at the connecting portions between the chips can be evaluated. Likewise, by evaluating the operating current in the modes of (3) and (4), the current consumed on the output signal side of the inner pads 4C and 5C at the connecting portion between the chips can be evaluated. Thus, the presence or absence of current abnormality at the connecting portions between the chips can be detected through these evaluations of the current (monitoring the abnormal current or leaked current at the pads 4A, 4B, 4C, 5A, 5B and 5C).

As described above, in accordance with the first embodiment, the operating current of only the second chip 2 and at the connecting portions between the chips can be evaluated. This embodiment is efficient as a means for debagging the chips at the initial stage of development and means for analyzing the cause of reliability failure after mass production.

### Embodiment 2

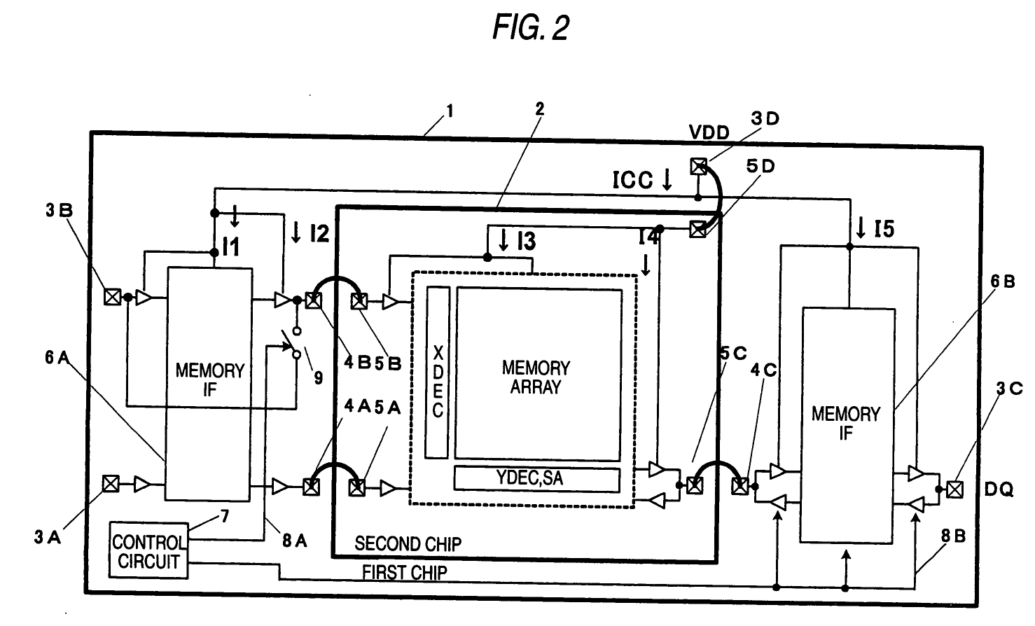

FIG. 2 is a block diagram of a semiconductor device according to the second embodiment of this invention. In the first embodiment, where the operating current of the second chip 2 is measured, the current measurement must be made twice (the above operating current measuring modes (2) and (4)). In this embodiment, the address terminal 3B is connected to the inner pad 4B through a switch element 9. Only when the operating current is measured, the switch element 9 is turned on by the control signal 8A produced from the control circuit 7. The current consumed in the path via the switch element 9 is smaller than that consumed in the interface circuit 6A.

The interface circuit 6A generally includes elements such as a selector circuit, a latch circuit and a flip-flop although it includes various elements depending on a system to be applied. The interface circuit may require an operating current larger than the current consumed in the path via only the switch element 9. The inner pads 5A and 5B of the second chip 2 is not driven by the output circuit provided at the inner pads 4A and 4B but driven by a drive circuit outside the package. Where the operating current of the second chip 2 is measured, therefore, the current consumed in the path via the switch element 9 is smaller.

Specifically, in the second embodiment, the currents I1 and I2 consumed in the first chip 1 are considered to be not present. For this reason, by executing only the operating current measuring mode of (4), the operating current of only the second chip 2 can be measured.

As described above, in accordance with the second embodiment, by measuring the operating current once by turn-on of the switch element 9, the operating current of only the second chip 2 and at the connecting portions between the chips can be evaluated. This embodiment is efficient as a simple means for debagging the chips at the initial stage of development and means for analyzing the cause of reliability failure after mass production.

### Embodiment 3

The first embodiment and second embodiment are directed to the means for measuring the operating current of the second chip 2. On the other hand, the third embodiment is directed to the means for measuring a static current. In the first and second embodiments, the operating current could be measured individually for each chip. The static current cannot be measured for each chip. The reason is as follows. Since the VDD terminals 3D and 5D which are power source terminals are commonly connected for the first chip 1 and second chip 2, if there is abnormality in the static current or a leak current of the power source in either chip, the leak current flows to the first chip 1 or second chip 2 through the common VDD terminal 3D, 5D. The leak current, therefore, cannot be discriminated in the first chip 1 and second chip 2.

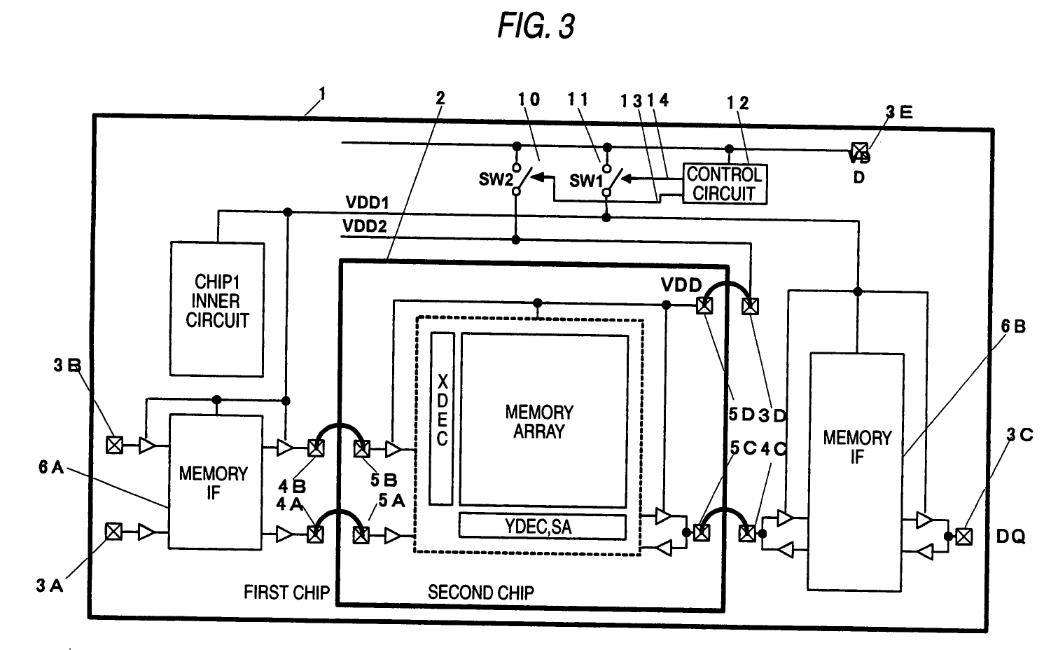

FIG. 3 is a block diagram of a semiconductor device according to the third embodiment of this invention. In the third embodiment, a switch element (SW1) 10 and a switch element (SW2) 11 are connected to a VDD terminal 3E which is an outer pad. The switch elements 10 and 11 are on/off controlled by control signals 13 and 14 which are created by a control circuit 12 supplied with power from the VDD terminal 3E. The switch element 11 is connected to a power source line VDD1 for the first chip, whereas the switch element 10 is connected to a power source line VDD2 for the second chip 2. The power source line VDD2 supplies power to the second chip 2 through the inner pad 3D on the first chip 1 and the inner pad 5D on the second chip 2.

The on/off control of the switch elements 10 and 11 will be explained referring to Table 1.

TABLE 1

| Mode | SW1 | SW2 |
|---|---|---|
| Normal Operation | ON | ON |
| Measurement of Static | ON | OFF |
| Current in First Chip | | |
| Measurement of Static | OFF | ON |
| Current in Second Chip | | |
| Measurement of Static | OFF | OFF |
| Current in Control Circuit | | |

During the normal operation, the switch elements 10 and 11 are ON so that the external power source VDD is supplied to the first chip 1 and second chip 2. Where the static current in the first chip 1 is measured, SW1 is ON and the current path to the second chip 2 is stopped. In this way, the static current in only the first chip 1 can be measured. Where the static current in the second chip 2 is measured, only SW2 is ON and the current path to the first chip 1 is stopped. In this way, the static current in only the second chip 2 can be measured.

Now, since a leak current may be produced in the path leading to the external power source VDD, with the switch elements 10 and 11 being OFF, the static current in the external power source VDD is measured. By measuring the static current in each of these three modes, the static currents in only the first chip 1 and only the second chip 2 can be measured.

In accordance with the third embodiment, the static currents in only the first chip 1 and only the second chip 2 can be evaluated.

This embodiment is efficient as a means for debagging the chips at the initial stage of development and means for analyzing the cause of reliability failure after mass production.

### Embodiment 4

The first to third embodiments provide the means for measuring the currents consumed in the first chip 1 and second chip 2. On the other hand, the fourth embodiment provides a means for monitoring signal delay between the first chip 1 and the second chip 2.

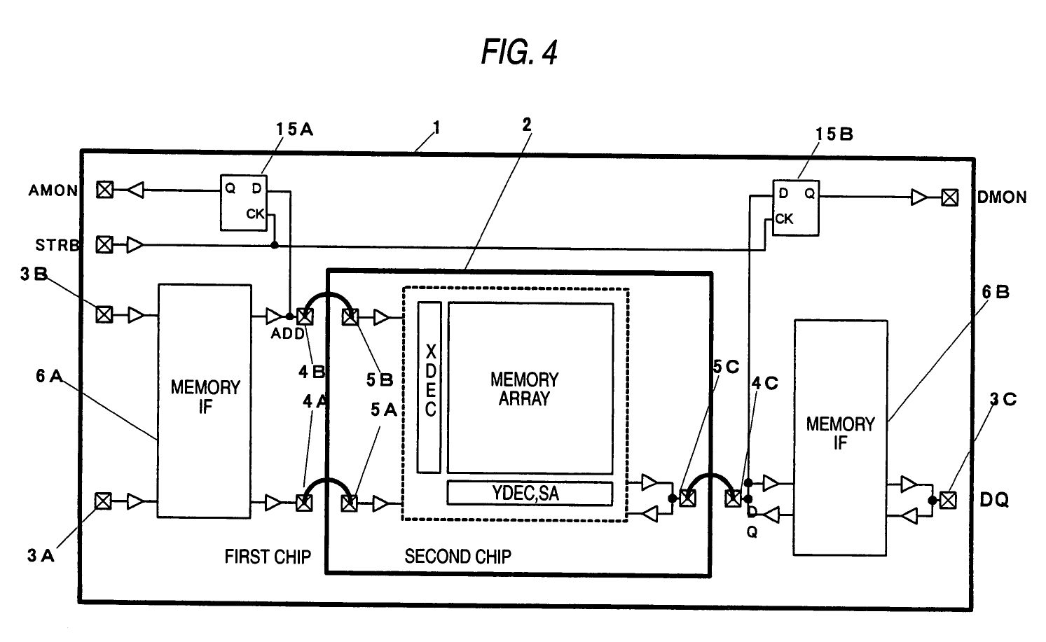

FIG. 4 is a block diagram of a semiconductor device according to the fourth embodiment of this invention. FIG. 4 illustrates a case where the second chip 2 is a memory. In the case of the memory, the access time from when an address is inputted to when a data is outputted is an important parameter. As regards the package in the SIP structure, like the consumed current, the status of the access time within the package cannot be monitored externally.

For example, assuming that the memory is a flash memory, the flash memory is generally deteriorated in its memory cell characteristic (Vt) through repetition of rewrite or read. Specifically, the memory cell current in read-out is attenuated so that the access time may be deteriorated. In such a case, it is important to realize that the access time to the memory can be monitored outside the package. This is because after shipping to a market product failure may occur owing to deterioration in reliability so that the failure analysis must be executed in the SIP status.

In the fourth embodiment, in order to monitor the access time to the second chip 2, i.e. to monitor the delayed state at the inner pad 4B (first bonding pad), which is an ADD terminal of the first chip 1, and at the inner pad 4C (second bonding pad), which is a DQ terminal of the first chip 1, first and second flip-flops 15A and 15B are provided. Each of the clock terminals CK of the flip-flops 15A and 15B is externally supplied with a STRB signal for both ADD terminal and DQ terminal.

The input terminals D of the flip-flops 15A and 15B are directly connected to the inner pad 4B serving as the ADD terminal and the inner pad 4C serving as the DQ terminal, respectively. The output terminals Q of the flip-flops 15A and 15B are connected to an external terminal AMON for the ADD terminal and an external terminal DMON for the DQ terminal, respectively.

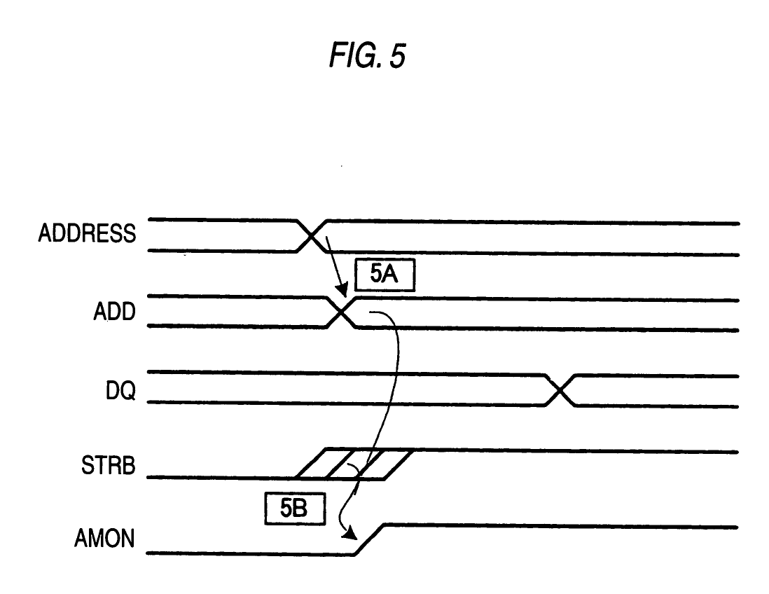

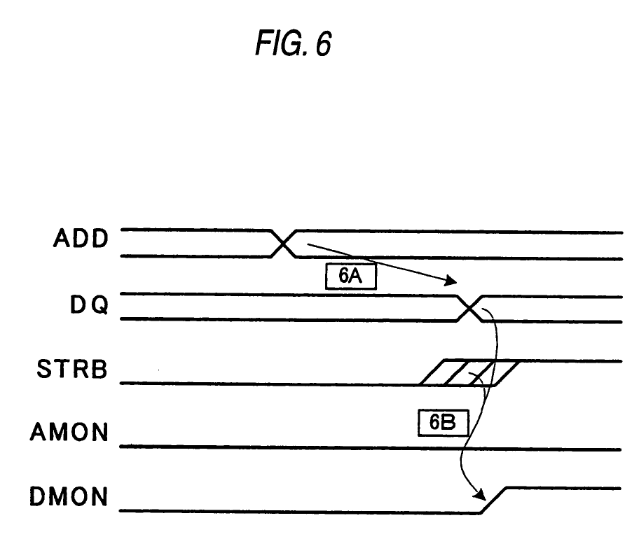

FIGS. 5 and 6 are timing charts for explaining the operation in the fourth embodiment. FIG. 5 shows the delayed status of the signal at the ADD terminal. When an address is externally inputted to the address terminal 3B, the data at the ADD terminal of the inner pad 4B varies owing to a delay (arrow 5A in FIG. 5). On the other hand, as seen from FIG. 5, the STRB signal is externally inputted to scan the rising edge closely in the vicinity of the timing when the signal at the ADD terminal varies.

When the STRB signal rises at the timing when the signal at the ADD terminal varies, the flip-flop 15A fetches the level transition of the signal at the ADD terminal so that the level transition of the signal at the ADD terminal is transferred to the external terminal AMON as it is(arrow 5B in FIG. 5). In this way, by shifting the rising edge of the STRB signal, the delayed status of the signal at the ADD terminal of the inner pad 4B can be monitored.

FIG. 6 shows the delayed status of the signal at the DQ terminal 4C on the output side. When an address is externally inputted to the second chip 2, the data is outputted from the second chip 2 so that the signal at the DQ terminal 4C varies (arrow 6A in FIG. 6). On the other hand, as seen from FIG. 6, the STRB signal is externally inputted to scan the rising edge closely in the vicinity of the timing when the signal at the DQ terminal 4C varies.

When the STRB signal rises at the timing when the signal at the ADD terminal varies, the flip-flop 15B fetches the level transition of the signal at the DQ terminal 4C so that the level transition of the signal at the DQ terminal 4C is transferred to the external terminal AMON as it is (arrow 6B in FIG. 6). In this way, by shifting the rising edge of the STRB signal, the delayed status of the signal at the DQ terminal 4C can be monitored.

In this way, in accordance with the fourth embodiment, at the timings shown in FIGS. 5 and 6, the delayed status of the address and data within the chip can be monitored. Thus, the access time from the first chip 1 to the second chip 2 can be measured. Accordingly, this embodiment is efficient as a means for debagging the chips at the initial stage of development and means for analyzing the cause of reliability failure after mass production.

### Embodiment 5

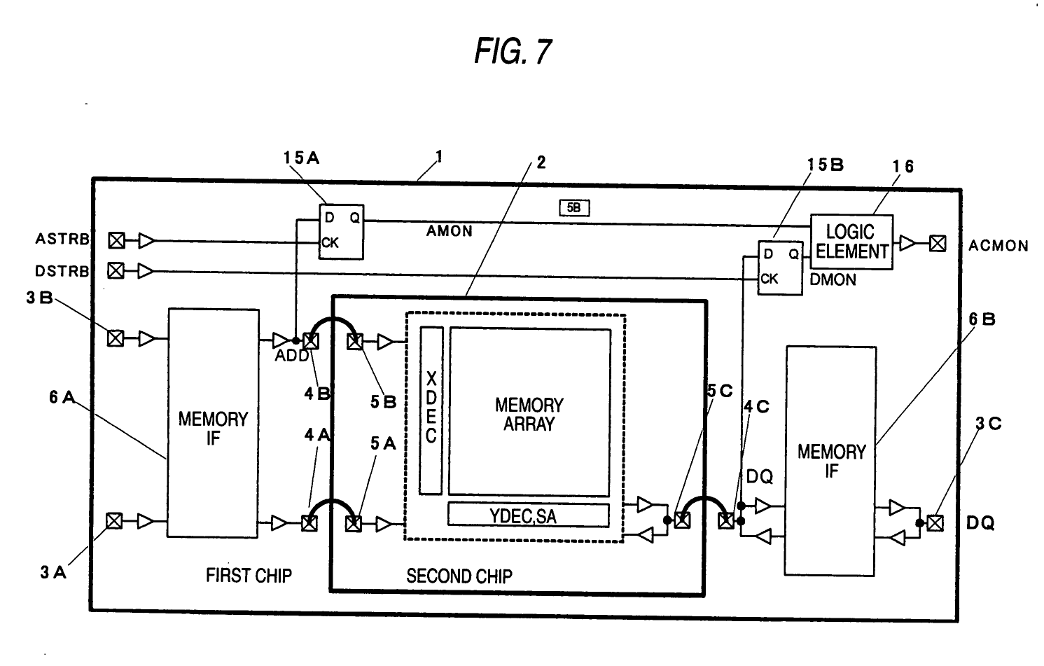

FIG. 7 is a block diagram of a semiconductor device according to the fifth embodiment of this invention. Like the fourth embodiment, this embodiment provides the means for monitoring the access time. Like the fourth embodiment, the inner pads 4B and 4C which are the ADD terminal and DQ terminal of the first chip 1 are connected to the input terminals D of the flip-flops 15A and 15B, respectively. An external terminal ASTRB is connected to the clock terminal CK of the flip-flop 15A corresponding to the ADD terminal, whereas an external terminal DSTRB is connected to the clock terminal CK of the flip-flop 15B corresponding to the DQ terminal.

On the other hand, a logic element 16 is connected to the output terminal Q (signal line AMON) of the flip-flop 15A corresponding to the ADD terminal and to the output terminal Q (signal line DMON) of the flip-flop 15B corresponding to the DQ terminal. The output from the logic element 16 is connected to an external terminal ACMON.

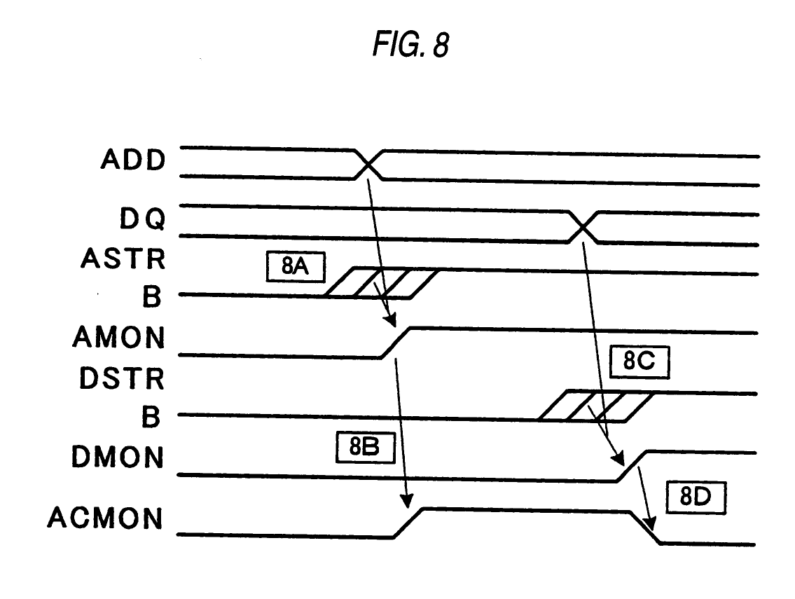

FIG. 8 is a timing chart for explaining the operation in the fifth embodiment. When an address is externally inputted to the address terminal 3B, the signal at the ADD terminal of the inner pad 4B varies owing to a delay. On the other hand, as seen from FIG. 8, the ASTRB signal is externally inputted to scan the rising edge closely in the vicinity of the timing when the signal at the ADD terminal varies.

When the ASTRB signal rises at the timing when the signal at the ADD terminal varies, the flip-flop 15A fetches the level transition of the signal at the ADD terminal so that the level transition of the signal at the ADD terminal is transferred to the signal line AMON as it is(arrow 8A in FIG. 8). Simultaneously, the output from the logic element 16 varies so that the status of the external terminal ACMON transits (arrow 8B in FIG. 8). In this way, by shifting the rising edge of the ASTRB signal, the delayed status of the signal at the ADD terminal of the inner pad 4B can be monitored.

When an address is externally inputted to the second chip 2, the data is outputted from the second chip 2 so that the signal at the DQ terminal 4C varies. On the other hand, as seen from FIG. 8, the DSTRB signal is externally inputted to the clock terminal CK of the second flip-flop 15B to scan the rising edge closely in the vicinity of the timing when the signal at the DQ terminal 4C varies.

When the STRB signal rises at the timing when the signal at the DQ terminal varies, the flip-flop 15B fetches the level transition of the signal at the DQ terminal so that the level transition of the signal at the DQ terminal is transferred to the signal line DMON as it is(arrow 8C in FIG. 8). Simultaneously, the output from the logic element 16 varies so that the status of the external terminal ACMON transits (arrow 8D in FIG. 8).

In this way by shifting the rising edge of the DSTRB signal, the delayed status of the signal at the DQ terminal of the inner pad 4C can be monitored. Namely, the access time within the package can be monitored at only the ACMON terminal. Incidentally, the logic element 16 may be an RS flip-flop which shifts an output level when a transition in two signals is detected.

In this way, in accordance with the fifth embodiment, at the timings shown in FIG. 8, the delayed status of the address and data within the chip can be monitored. As in the fourth embodiment, the access time is not measured twice for the address and data. Without increasing the number of external pins, the access time from the first chip 1 to the second chip 2 can be obtained by the measurement once made. Accordingly, this embodiment is efficient as a means for debagging the chips at the initial stage of development and means for analyzing the cause of reliability failure after mass production.

### Embodiment 6

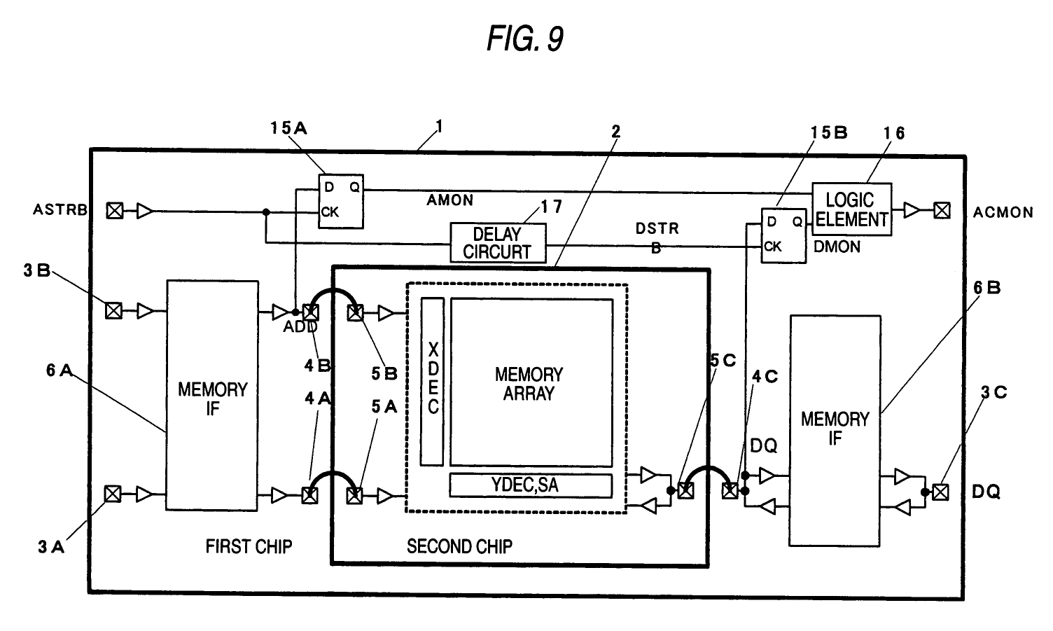

FIG. 9 is a block diagram of a semiconductor device according to the sixth embodiment of this invention. Like the fourth embodiment, this embodiment provides the means for monitoring the access time. Like the fourth embodiment, the inner pads 4B and 4C which are the ADD terminal and DQ terminal of the first chip 1 are connected to the input terminals D of the flip-flops 15A and 15B, respectively. An external terminal ASTRB is connected to the clock terminal CK of the flip-flop 15A corresponding to the ADD terminal.

A DSTRB signal which is a delayed signal created by a delay circuit 17 on the basis of the ASTRB signal is connected to the clock terminal CK of the flip-flop 15B corresponding to the DQ terminal.

On the other hand, a logic element 16 is connected to the output terminal Q (signal line AMON) of the flip-flop 15A corresponding to the ADD terminal and to the output terminal Q (signal line DMON) of the flip-flop 15B corresponding to the DQ terminal. The output from the logic element 16 is connected to an external terminal ACMON.

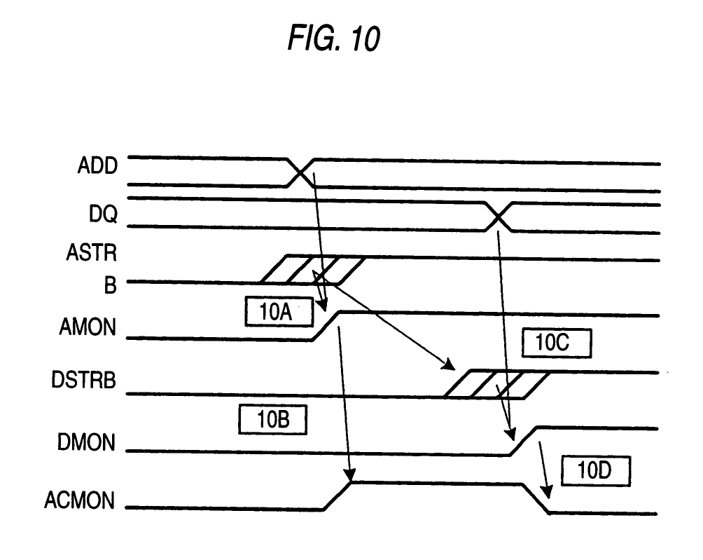

FIG. 10 is a timing chart for explaining the operation in the fifth embodiment. When an address is externally inputted to the address terminal 3B, the signal at the ADD terminal of the inner pad 4B varies owing to a delay. On the other hand, as seen from FIG. 10, the ASTRB signal is externally inputted to scan the rising edge closely in the vicinity of the timing when the signal at the ADD terminal varies.

When the ASTRB signal rises at the timing when the signal at the ADD terminal varies, the flip-flop 15A fetches the level transition of the signal at the ADD terminal so that the level transition of the signal at the ADD terminal is transferred to the signal line AMON as it is(arrow 10A in FIG. 10). Simultaneously, the output from the logic element 16 varies so that the status of the external terminal ACMON transits (arrow 10B in FIG. 10). In this way, by shifting the rising edge of the ASTRB signal, the delayed status of the signal at the ADD terminal of the inner pad 4B can be monitored.

When an address is externally inputted to the second chip 2, the data is outputted from the second chip 2 so that the signal at the DQ terminal 4C varies. On the other hand, if the access time to the second chip 2 is previously set for the delayed signal DSTR of the ATRB signal by the delay circuit 17, when the ATRB signal is scanned, the DSTRB signal is scanned in the manner delayed by the access time.

When the DSTRB signal rises at the timing when the signal at the DQ terminal varies, the flip-flop 15B fetches the level transition of the signal at the DQ terminal so that the level transition of the signal at the DQ terminal is transferred to the signal line DMON as it is(arrow 10C in FIG. 10). Simultaneously, the output from the logic element 16 varies so that the status of the external terminal ACMON transits (arrow 10D in FIG. 10).

In this way, by shifting the rising edge of the ASTRB signal, whether or not the signal state of the DQ terminal of the inner pad 4C has transited by a desired delay time can be monitored. Namely, the access time within the package can be monitored at only the ACMON terminal.

The logic element 16 may be an RS flip-flop which shifts an output level when a transition in two signals is detected. The delay time set in the delay circuit 17, if it can be controlled externally, can be evaluated more accurately.

In this way, in accordance with the sixth embodiment, at the timings shown in FIG. 10, the delayed status of the address and data within the chip can be monitored. As in the fourth embodiment, the access time is not measured twice for the address and data. The number of pins for external inputting can be reduced by one as compared with the fifth embodiment. Further, the access time from the first chip 1 to the second chip 2 can be obtained by the measurement once made. Accordingly, this embodiment is efficient as a means for debagging the chips at the initial stage of development and a more simple means for analyzing the cause of reliability failure after mass production.

### Embodiment 7

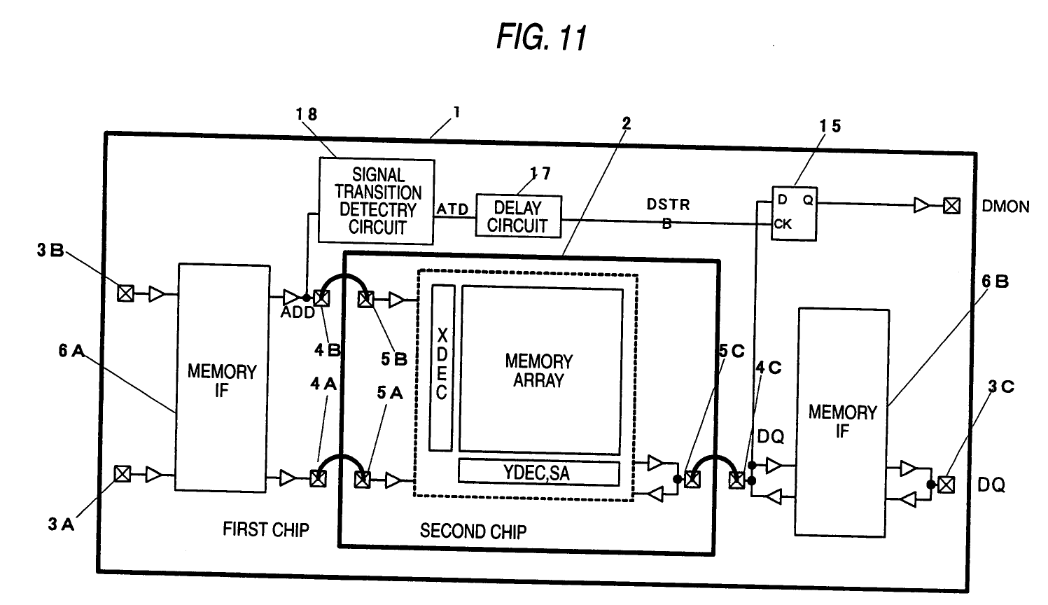

FIG. 11 is a block diagram of a semiconductor device according to the seventh embodiment of this invention. Like the fourth embodiment, this embodiment also provides the means for monitoring the access time. Like the fourth embodiment, the inner pad 4C of the DQ terminal on the first chip 1 is connected to the input terminal D of a flip-flop 15. On the other hand, the inner pad 4B of the ADD terminal is connected to the input side of a signal transition detecting circuit 18.

The output from the signal transition detecting circuit 18 is connected to a delay circuit 17 which creates a DSTRB signal. To the clock terminal CK of the flip-flop 15 corresponding to the DQ terminal, the delayed signal, the DSTRB signal created by the delay signal is connected. To the output terminal Q (signal line DMON) of the flip-flop 15 corresponding to the DQ terminal, an external terminal DMON is connected.

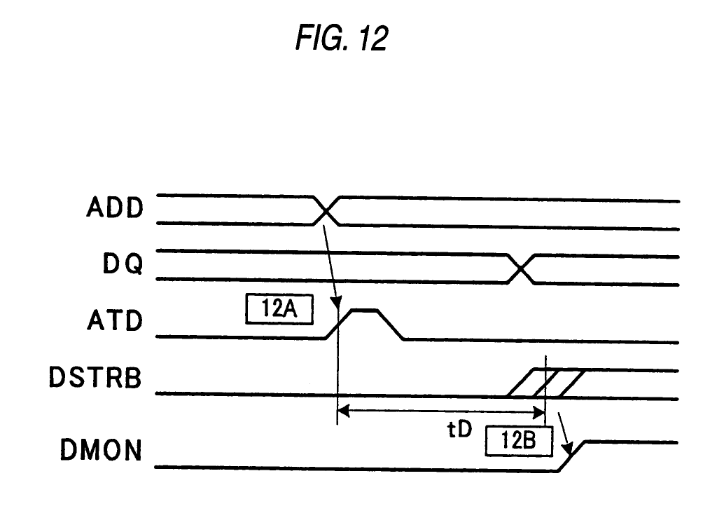

FIG. 12 is a timing chart for explaining the operation in the fifth embodiment. When an address is externally inputted to the address terminal 3B, the signal at the ADD terminal of the inner pad 4B varies owing to a delay. Simultaneously, an ATB pulse signal is produced from the signal transition detecting circuit 18 (arrow 12A in FIG. 12). On the basis of the ATB signal, the delay time tD created by the delay circuit 17, i.e the DSTRB signal varies.

When an address is externally inputted to the second chip 2, the data is outputted from the second chip 2 so that the signal at the DQ terminal of the inner pad 4C varies. On the other hand, if the access time to the second chip 2 is previously set for the delay signal DSTRB by the delay circuit 17, the DSTRB signal varies by the access time with a change in the address. When the DSTRB signal rises at the timing when the signal at the DQ terminal varies, the flip-flop 15 fetches the level transition of the signal at the DQ terminal so that the level transition of the signal at the DQ terminal is transferred to the signal line DMON as it is(arrow 12B in FIG. 12). Simultaneously, the output from the logic element 16 varies so that the status of the external terminal ACMON transits (arrow 10D in FIG. 10).

In this way, when the address changes, whether or not the signal state of the DQ terminal of the inner pad 4C has transited by a desired delay time can be monitored. Namely, without scanning the signal externally, the access time within the package can be monitored at only the ACMON terminal. Incidentally, the delay time set in the delay circuit 17, if it can be controlled externally, can be evaluated more accurately.

In this way, in accordance with the seventh embodiment, at the timings shown in FIG. 12, the delayed status of the data within the chips can be monitored. As in the fourth embodiment, the access time is not measured twice for the address and data. The number of pins for external inputting can be reduced by one as compared with the sixth embodiment. Further, the access time from the first chip 1 to the second chip 2 can be obtained by the measurement once made. Accordingly, this embodiment is efficient as a means for debagging the chips at the initial stage of development and a more simple means for analyzing the cause of reliability failure after mass production.

In accordance with the semiconductor device according to this invention, since the operation of the interface circuit can be controlled by a control signal, if the operation of the interface circuit is stopped partially or completely, the first chip and the second chip can be discriminated from each other so that the operating current of the individual chip and that of the connecting portion between the chips can be measured. Further, if the power source line for each chip is individually provided, the static current for each chip can be measured. Furthermore, there are provided the first flip-flop for fetching the signal to be inputted from the first chip to the second chip and the second flip-flop for fetching the signal to be outputted from the second chip so that the outputs from the first and second flip-flops are outputted to the outside of the package. In this configuration, the delayed status of the signal between the chips can be monitored, thereby measuring the access time in a real load state at the connecting portion between the chips within the package. Accordingly, the semiconductor device according to this invention is useful as a semiconductor device in which a plurality of chips are mounted in the same package and are connected to one another.

1. A semiconductor device; comprising:
a plurality of chips, mounted in a same package and connected to one another by wires or bumps, the plurality of chips including:
a first chip, though which signal transmission/reception is performed between the inside and the outside of the package; and
a second chip, connected to the first chip within the package;
wherein the first chip includes an interface circuit for supplying a signal to all signal terminals of the second chip and
the operation of the interface circuit is controlled so as to be stoppable by a control signal.

2. The semiconductor device according to claim 1, further comprising:
a switch element, connecting a part of an external signal terminal through which the signal is externally supplied to the first chip, to an inner signal terminal of the first chip through which the signal is supplied to the second chip;
wherein the switch element is on/off controlled by the control signal.

3. A semiconductor device, comprising:
a plurality of chips, mounted in a same package and connected to one another by wires or bumps; the plurality of chips including:
a first chip, though which signal transmission/reception is performed between the inside and the outside of the package; and
a second chip, connected to the first chip within the package;
wherein the semiconductor device further comprises:
a first power source line, supplying a power source to the first chip through a first switch element; and
a second power source line, supplying the power source to the second chip through a second switch element.

4. The semiconductor device according to claim 3, further comprising:
a control circuit, actuated by the power source and controlling the first and second switch elements.

5. A semiconductor device, comprising:
a plurality of chips, mounted in the same package, and connected to one another by wires or bumps, the plurality of chips including:
a first chip, though which signal transmission/reception is performed between the inside and the outside of the package; and
a second chip, connected to the first chip within the package;
wherein the semiconductor device further comprises:
a first flip-flop, fetching the signal to be inputted from the first chip to the second chip;
a second flip-flop for fetching the signal to be outputted from the second chip and a terminal through which outputs from the first and the second flip-flop are outputted to the outside of the package.

6. A semiconductor device, comprising:
a plurality of chips, mounted in the same package and connected to one another by wires or bumps, the plurality of chips including:
a first chip, though which signal transmission/reception is performed between the inside and the outside of the package; and
a second chip, connected to the first chip within the package;
wherein the semiconductor device further comprises:
a first flip-flop, fetching the signal to be inputted from the first chip to the second chip;
a second flip-flop, fetching the signal to be outputted from the second chip at a different timing from that for the first flip-flop;
a logic element, making a logic operation of outputs from the first and second flip-flops; and
a terminal, through which the output from the logic element is outputted to the outside of the package.

7. The semiconductor device according to claim 6, further comprising:
a delay circuit, delaying a clock signal supplied to the first flip-flop and supplying the delayed clock signal to the second flip-flop.

8. The semiconductor device according to claim 7, wherein the delay circuit provides a delay time which is externally adjustable.

9. The semiconductor device, comprising:
a plurality of chips, mounted in the same package and connected to one another by wires or bumps, the plurality of chips including:
a first chip, though which signal transmission/reception is performed between the inside and the outside of the package; and
a second chip, connected to the first chip within the package;
wherein the semiconductor further comprises:
a signal transition detecting circuit, detecting a transition in the signal inputted from the first chip to the second chip;
a flip-flop, fetching the signal to be outputted from the second chip at an output timing of the signal transition detecting circuit; and
a terminal, through which the output from the flip-flop is outputted to the outside of the package.

10. The semiconductor device according to claim 9, further comprising:
a delay circuit, capable of delaying the output from the signal transition detecting circuit by any time by external adjustment.
